(19) United States
(12) Patent Application Publication
(10) Pub. No.: US 2022/0173301 A1
(43) Pub. Date: Jun. 2, 2022

(54) THIN-FILM PIEZOELECTRIC ACTUATOR

(71) Applicant: TDK CORPORATION, Tokyo (JP)

(72) Inventors: Wei XIONG, Hong Kong (CN); Mai Ru SHI, Hong Kong (CN); Fei HE, Hong Kong (CN)

(73) Assignee: TDK CORPORATION, Tokyo (JP)

(21) Appl. No.: 17/536,905

(22) Filed: Nov. 29, 2021

(30) Foreign Application Priority Data
Nov. 30, 2020 (CN) 202011372354.0

(51) Int. Cl. H01L 41/08; H01L 41/312; H01L 41/053; H01L 41/09; H01L 41/047

(52) U.S. Cl. CPC H01L 41/081; H01L 41/312; H01L 41/0477; H01L 41/09; H01L 41/0533

(57) ABSTRACT

A thin-film piezoelectric actuator includes: a substrate; a lower electrode laminated on the substrate; a laminated structure configured to be laminated on the lower electrode and including a plurality of thin-film piezoelectric films alternately laminated with an intermediate electrode between; an upper electrode laminated on the laminated structure; a first protective layer configured to be provided on an upper surface of the upper electrode and made of an alloy material containing iron, cobalt, and molybdenum; and a second protective layer configured to be provided at least on an upper surface of an end portion of the intermediate electrode that is not between the thin-film piezoelectric films, and made of an alloy material containing iron, cobalt, and molybdenum. The present invention provides a thin-film piezoelectric actuator that can achieve high performance and can effectively suppress the occurrence of cracks at the end portion of the piezoelectric film in the lower layer.

### FIELD

The present invention relates to a thin-film piezoelectric actuator.

### BACKGROUND

In recent years, thin-film piezoelectric elements using thin-film piezoelectric material instead of bulk piezoelectric materials have been increasingly put into practical applications. In such a thin-film piezoelectric element, piezoelectric elements are widely used as drive elements and applied in various fields such as MEMS structure jet, micro pump, micro mirror and piezoelectric ultrasonic transducer, because the piezoelectric elements may be deformed when an electrical field is applied. For example, such thin-film piezoelectric elements include a gyroscope sensor, a vibration sensor, a microphone, etc., which utilize the piezoelectric effect that converts the force applied to the piezoelectric thin film into voltage, and an actuator, an ink-jet head, a speaker, a buzzer, a resonator, etc. that utilize the reverse piezoelectric effect that deforms the piezoelectric thin film by applying a voltage to the piezoelectric thin film, etc.

For example, Patent Document 1 discloses a thin-film piezoelectric actuator including two piezoelectric layers (piezoelectric films) and three-layers electrodes arranged at intervals on both sides of each of the two piezoelectric layers. Compared with a thin-film piezoelectric actuator with only one piezoelectric layer, in this thin-film piezoelectric actuator, the performance of the thin-film piezoelectric actuator such as stroke, responsiveness, durability or the like can be doubled, thereby achieving higher performance, by setting two piezoelectric layers.

However, in the above-mentioned thin-film piezoelectric actuator, the piezoelectric layer is expanded and contracted by piezoelectric effect and a strain occurs, which may cause the piezoelectric layer to easily delaminate from the electrode. Therefore, when a voltage is applied to the electrode, breakdown may occur, which may cause cracks at the end of the piezoelectric layer of the lower layer.

### CITATION LIST

Patent Document 1: CN110121422A

### SUMMARY

The present invention is the result of intensive research in view of the above-mentioned problems, and its object is to provide a thin-film piezoelectric actuator that can achieve high performance and can effectively suppress the occurrence of cracks at the end portion of the piezoelectric film in the lower layer.

In order to achieve the above-mentioned object, a thin-film piezoelectric actuator according to an aspect of the present invention is characterized by comprising: a substrate; a lower electrode laminated on the substrate; a laminated structure configured to be laminated on the lower electrode and including a plurality of thin-film piezoelectric films alternately laminated with an intermediate electrode sandwiched in between; an upper electrode laminated on the laminated structure; a first protective layer configured to be provided on an upper surface of the upper electrode and made of an alloy material containing iron, cobalt, and molybdenum; and a second protective layer configured to be provided at least on an upper surface of the end portion of the intermediate electrode that is not sandwiched between the thin-film piezoelectric films, and made of an alloy material containing iron, cobalt, and molybdenum. In this way, the performance of the thin-film piezoelectric actuator such as stroke, responsiveness, durability or the like can be greatly improved and achieve higher performance, by providing multiple thin-film piezoelectric films. In addition, by providing a protective layer on the upper surface of the upper electrode and the upper surface of the end portion of the intermediate electrode that is not sandwiched between the thin-film piezoelectric films, the compressive stress of the protective layer can be used to prevent the delamination between the thin-film piezoelectric film and the electrode due to strain of the thin-film piezoelectric film, thereby effectively suppressing the occurrence of cracks at the end portion of the underlying piezoelectric film.

In addition, in the thin-film piezoelectric actuator according to one aspect of the present invention described above, it is preferable that the second protective layer is continuously provided on the entire surface of the upper surface of the end portion of the intermediate electrode that is not sandwiched between the thin-film piezoelectric films and a part of an end surface of the thin-film piezoelectric film. As a result, it is possible to be more effective to suppress the occurrence of cracks at the end portion of the piezoelectric film in the lower layer.

In addition, in the thin-film piezoelectric actuator according to one aspect of the present invention described above, it is preferable that the second protective layer is continuously provided on the entire surface of the upper surface of the end portion of the intermediate electrode that is not sandwiched between the thin-film piezoelectric films, the entire surface of an end surface of the thin-film piezoelectric film, and a part of the upper surface of the thin-film piezoelectric film. As a result, it is possible to be more effective to suppress the occurrence of cracks at the end portion of the piezoelectric film in the lower layer.

In addition, in the thin-film piezoelectric actuator according to one aspect of the present invention described above, it is preferable that the end surface of the thin-film piezoelectric film is an inclined surface that is inclined with respect to the direction in which the plurality of thin-film piezoelectric films are laminated.

In addition, in the thin-film piezoelectric actuator according to one aspect of the present invention described above, it is preferable that the end surface of the thin-film piezoelectric film is a vertical surface parallel to the direction in which the plurality of thin-film piezoelectric films are laminated.

In addition, in the thin-film piezoelectric actuator according to one aspect of the present invention described above, it is preferable that further comprising a third protective layer configured to be provided on an upper surface of the end portion of the lower electrode that is not sandwiched between the substrate and the laminated structure and made of an alloy material containing iron, cobalt, and molybdenum. Thus, it is possible to prevent peeling of the electrode by providing the third protective layer on the upper surface of the lower electrode.

In addition, in the thin-film piezoelectric actuator according to one aspect of the present invention described above, it is preferable that further comprising a fourth protective layer configured to be provided on a lower surface of the lower electrode and made of an alloy material containing iron, cobalt, and molybdenum, the lower electrode is laminated on the substrate via the fourth protective layer. Thus, the first protective layer is provided on the upper surface of the upper electrode and the fourth protective layer is provided on the lower surface of the lower electrode to sandwich each thin-film piezoelectric film, so that compressive stress can be applied to each thin-film piezoelectric film. Therefore, the strength of the thin film piezoelectric actuator can be further improved.

According to one aspect of the present invention, there is provided a thin-film piezoelectric actuator that can achieve high performance and can effectively suppress the occurrence of cracks at the end portion of the piezoelectric film in the lower layer.

### BRIEF DESCRIPTION OF THE DRAWINGS

FIG. 1 is a schematic cross-sectional view showing the general structure of the thin-film piezoelectric actuator according to the first embodiment.

FIG. 2 is a schematic cross-sectional view showing the general structure of the thin-film piezoelectric actuator according to the second embodiment.

FIG. 3 is a schematic cross-sectional view showing the general structure of the thin-film piezoelectric actuator according to the third embodiment.

FIG. 4 is a schematic cross-sectional view showing the general structure of a thin-film piezoelectric actuator according to a fourth embodiment.

FIG. 5 is a schematic cross-sectional view showing the general structure of a thin-film piezoelectric actuator according to a fifth embodiment.

FIG. 6 is a schematic cross-sectional view showing the general structure of a thin-film piezoelectric actuator according to a modification of the first embodiment.

FIG. 7 is a schematic cross-sectional view showing the general structure of a thin film piezoelectric actuator according to a modification of the fourth embodiment

FIG. 8 is a schematic cross-sectional view showing the general structure of a thin film piezoelectric actuator according to a modification of the fifth embodiment

### DETAILED DESCRIPTION OF THE EMBODIMENT(S)

Hereinafter, preferred embodiments of the present invention will be described in detail with reference to the accompanying drawings. Here, in the description of the drawings, the same reference numerals denote the same or equivalent elements, duplicated descriptions thereof will be omitted.

### First Embodiment

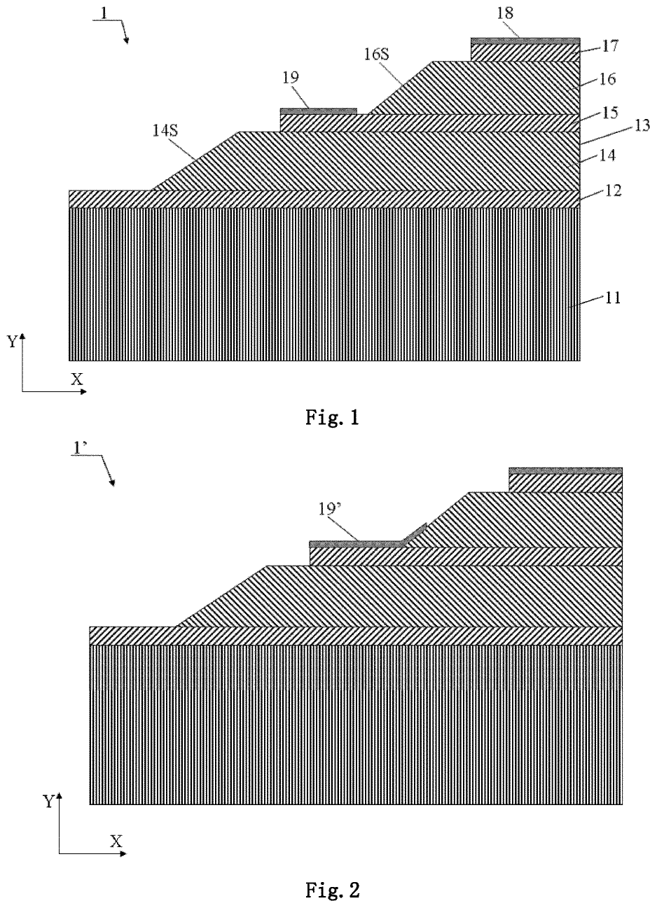

FIG. 1 is a schematic cross-sectional view showing the general structure of the thin-film piezoelectric actuator according to the first embodiment. As shown in FIG. 1, thin-film piezoelectric actuator 1 according to this embodiment includes a substrate 11, a lower electrode 12, a laminated structure 13, an upper electrode 17, a first protective layer 18, and a second protective layer 19

The substrate 11 is, for example, a silicon substrate, a silicon-on-insulator (SOI) substrate, a quartz glass substrate, a compound semiconductor substrate made of GaAs or the like, a sapphire substrate, a metal substrate made of stainless steel or the like, a MgO substrate, a SrTiO₃ substrate, or the like.

The lower electrode 12 is laminated on the substrate 11. The lower electrode 12 is a thin-film made of metal element which has Pt (it may include Au, Ag, Pd, Ir, Ru, Cu, in addition to Pt) as main component, and is formed on the substrate 11. A crystal structure of the lower electrode 12 is a face-centered cubic structure.

The laminated structure 13 is laminated on the lower electrode 12 and includes two thin-film piezoelectric films 14 and 16 alternately laminated along the laminating direction Y with an intermediate electrode 15 sandwiched in between. The thin-film piezoelectric films 14 and 16 are formed to be thin-film shape using piezoelectric materials such as lead zirconate titanate described by Pb (Zr,Ti) O₃ (which will also be referred to as “PZT” in the following) or the like. The thin-film piezoelectric films 14 and 16 are epitaxial films formed by epitaxial growth, and have a thickness of, for example, about 2 μm to 5 μm. In addition, a piezoelectric ceramics (much of them are ferroelectric substance) such as barium titanate, lead titanate or the like, or non-lead system piezoelectric ceramics not including lead are able to be used for the thin-film piezoelectric films 14 and 16 instead of using PZT. The thin-film piezoelectric films 14, 16 are sputtered films formed by sputtering.

In addition, the thin-film piezoelectric film 14 has an inclined surface 14S that is inclined with respect to the laminating direction Y. The thin-film piezoelectric film 16 has an inclined surface 16S that is inclined with respect to the laminating direction Y.

The upper electrode 17 is laminated on the laminated structure 13. The upper electrode 17 is a thin-film made of metal material which has Pt (it may include Au, Ag, Pd, Ir, Ru, Cu, in addition to Pt) as main component, and is formed on the laminated structure 13. A crystal structure of the lower electrode 17 is a face-centered cubic structure.

The first protective layer 18 is provided on the upper surface of the upper electrode 17. The first protective layer 18 is formed using, for example, an alloy material which has iron (Fe) as main component. The first protective layer 18 is preferably formed using an alloy material containing Fe and at least any one selected from Co, Mo, Au, Pt, Al, Cu, Ag, Ta, Cr, Ti, Ni, Ir, Nb, Cs, Ba, V, W, and Ru. The first protective layer 18 is further preferably composed of an alloy material containing iron (Fe), cobalt (Co), and molybdenum (Mo). The first protective layer 18 can be formed by physical vapor deposition such as ion beam deposition, sputtering, vacuum evaporation, molecular beam epitaxy, or an ion plating, etc.

The second protective layer 19 is provided on the upper surface of the end portion of the intermediate electrode 15 that is not sandwiched between the thin-film piezoelectric films 14 and 16. The second protective layer 19 is the same as the first protective layer 18 and is formed using, for example, an alloy material which has iron (Fe) as main component. The second protective layer 19 is preferably formed using an alloy material containing Fe and at least any one selected from Co, Mo, Au, Pt, Al, Cu, Ag, Ta, Cr, Ti, Ni, Ir, Nb, Cs, Ba, V, W, and Ru. The second protective layer 19 is further preferably composed of an alloy material containing iron (Fe), cobalt (Co), and molybdenum (Mo). The second protective layer 19 can be formed by a physical vapor deposition such as ion beam deposition, sputtering, a vacuum evaporation, molecular beam epitaxy, or ion plating, etc.

In this way, the thin-film piezoelectric actuator according to the embodiment achieves the following effects: the performance of the thin-film piezoelectric actuators such as stroke, responsiveness, durability or the like can be greatly improved and achieve higher performance by providing multiple thin-film piezoelectric films. In addition, by providing a protective layer on the upper surface of the upper electrode and the upper surface of the end portion of the intermediate electrode that is not sandwiched between the thin-film piezoelectric films, the compressive stress of the protective layer can be used to prevent the delamination between the thin-film piezoelectric film and the electrode due to the strain of thin-film piezoelectric film, thereby effectively suppressing the occurrence of cracks at the end portion of the underlying piezoelectric film.

### Second Embodiment

FIG. 2 is a schematic cross-sectional view showing the general structure of the thin-film piezoelectric actuator according to the second embodiment. The difference between the thin-film piezoelectric actuator according to this embodiment and the thin-film piezoelectric actuator according to the first embodiment lies in the structure of the second protective layer. The other structure of the thin-film piezoelectric actuator according to this embodiment is the same as that of the thin-film piezoelectric actuator according to the first embodiment, and a further description will be omitted.

As shown in FIG. 2, the thin-film piezoelectric actuator 1′ according to the embodiment includes a second protective layer 19′. The second protective layer 19′ is continuously provided on the entire upper surface of the end portion of the intermediate electrode 15 that is not sandwiched between the thin-film piezoelectric films 14, 16 and a part of the end surface 16S of the thin-film piezoelectric film 16.

In addition to the same effects as the above-described first embodiment, the thin-film piezoelectric actuator according to this embodiment can be more effective to suppress the occurrence of cracks at the end of the piezoelectric film in the lower layer.

### Third Embodiment

FIG. 3 is a schematic cross-sectional view showing the general structure of the thin-film piezoelectric actuator according to the third embodiment. As shown in FIG. 3, the thin-film piezoelectric actuator 10 according to the embodiment includes a substrate 101, a lower electrode 102, a laminated structure 103, an upper electrode 107, a first protective layer 108, and a second protective layer 109

The substrate 101 is, for example, a silicon substrate, a silicon-on-insulator (SOI) substrate, a quartz glass substrate, a compound semiconductor substrate made of GaAs or the like, a sapphire substrate, a metal substrate made of stainless steel or the like, a MgO substrate, a SrTiO₃ substrate, or the like.

The lower electrode 102 is laminated on the substrate 101. The lower electrode 102 is a thin-film made of metal element which has Pt (it may include Au, Ag, Pd, Ir, Ru, Cu, in addition to Pt) as main component, and is formed on the substrate 101. A crystal structure of the lower electrode 102 is a face-centered cubic structure.

The laminated structure 103 is laminated on the lower electrode 102 and includes two thin-film piezoelectric films 104 and 106 alternately laminated along the laminating direction Y with an intermediate electrode 105 sandwiched in between. The thin-film piezoelectric films 104 and 106 are formed to be thin-film shape using piezoelectric materials such as lead zirconate titanate described by Pb (Zr,Ti) O₃ (which will also be referred to as “PZT” in the following) or the like. The thin-film piezoelectric films 104 and 106 are epitaxial films formed by epitaxial growth, and have a thickness of, for example, about 2 μm to 5 μm. In addition, a piezoelectric ceramics (much of them are ferroelectric substance) such as barium titanate, lead titanate or the like, or non-lead system piezoelectric ceramics not including lead are able to be used for the thin-film piezoelectric films 104 and 106 instead of using PZT. The thin-film piezoelectric films 104 and 106 are sputtered films formed by sputtering.

In addition, the thin-film piezoelectric film 104 has a vertical surface 104S parallel to the laminating direction Y. The thin-film piezoelectric film 106 has a vertical surface 106S parallel to the laminating direction Y.

The upper electrode 107 is laminated on the laminated structure 103. The upper electrode 107 is a thin-film made of metal material which has Pt (it may include Au, Ag, Pd, Ir, Ru, Cu, in addition to Pt) as main component, and is formed on the laminated structure 103. A crystal structure of the lower electrode 107 is a face-centered cubic structure.

The first protective layer 108 is provided on the upper surface of the upper electrode 107. The first protective layer 108 is formed using, for example, an alloy material which has iron (Fe) as main component. The first protective layer 108 is preferably formed using an alloy material containing Fe and at least any one selected from Co, Mo, Au, Pt, Al, Cu, Ag, Ta, Cr, Ti, Ni, Ir, Nb, Cs, Ba, V, W, and Ru. The first protective layer 108 is further preferably composed of an alloy material containing iron (Fe), cobalt (Co), and molybdenum (Mo). The first protective layer 108 can be formed by physical vapor deposition such as ion beam deposition, sputtering, vacuum evaporation, molecular beam epitaxy, or an ion plating, etc.

The second protective layer 109 is provided on the entire surface of the upper surface of the end portion of the intermediate electrode 105 that is not sandwiched between the thin-film piezoelectric films 104 and 106, the entire end surface 106S of the thin film piezoelectric film 106, and a part of the upper surface of the thin film piezoelectric film 106. The second protective layer 109 is the same as the first protective layer 108, and is formed using, for example, an alloy material which has iron (Fe) as main component. The second protective layer 109 is preferably formed using an alloy material containing Fe and at least any one selected from Co, Mo, Au, Pt, Al, Cu, Ag, Ta, Cr, Ti, Ni, Ir, Nb, Cs, Ba, V, W, and Ru. The second protective layer 109 is further preferably composed of an alloy material containing iron (Fe), cobalt (Co), and molybdenum (Mo). The second protective layer 109 can be formed by physical vapor deposition such as ion beam deposition, sputtering, vacuum evaporation, molecular beam epitaxy, or ion plating, etc.

In addition to the same effects as the above-described first embodiment, the thin-film piezoelectric actuator according to this embodiment can be more effective to suppress the occurrence of cracks at the end of the piezoelectric film in the lower layer.

### Fourth Embodiment

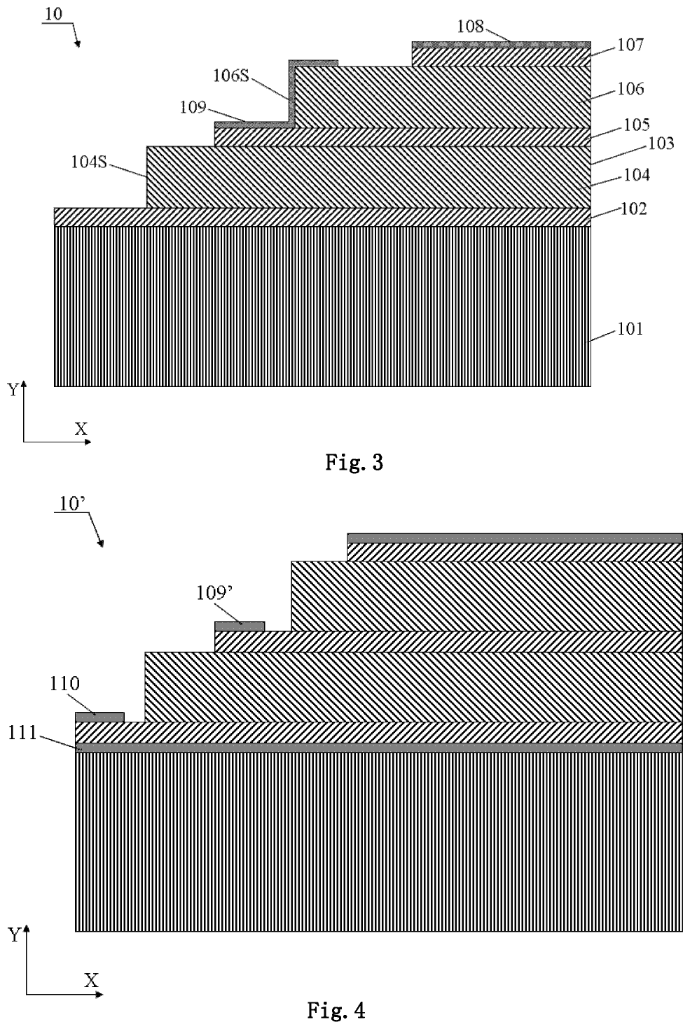

FIG. 4 is a schematic cross-sectional view showing the general structure of a thin-film piezoelectric actuator according to a fourth embodiment. The difference between the thin-film piezoelectric actuator according to the present embodiment and the thin-film piezoelectric actuator according to the third embodiment is that the second protective layer has a different arrangement form; and it also includes a third protective layer and a fourth protective layer. The other structure of the thin-film piezoelectric actuator according to this embodiment is the same as that of the thin-film piezoelectric actuator according to the third embodiment, and a further description will be omitted.

As shown in FIG. 4, the second protective layer 109′ of the thin-film piezoelectric actuator 10′ according to the present embodiment is different from the second protective layer 109 of the thin-film piezoelectric actuator 10 according to the third embodiment and is only provided on the upper surface of the end portion of the intermediate electrode 105 that is not sandwiched between the thin-film piezoelectric films 104 and 106.

In addition, the thin-film piezoelectric actuator 10′ according to the present embodiment further includes a third protective layer 110 and a fourth protective layer 111.

The third protective layer 110 is provided on the upper surface of the end portion of the lower electrode 102 that is not sandwiched between the substrate 101 and the laminated structure 103. The third protective layer 110 is formed using, for example, an alloy material which has iron (Fe) as main component. The third protective layer 110 is preferably formed using an alloy material containing Fe and at least any one selected from Co, Mo, Au, Pt, Al, Cu, Ag, Ta, Cr, Ti, Ni, Ir, Nb, Cs, Ba, V, W, and Ru. The third protective layer 110 is further preferably composed of an alloy material containing iron (Fe), cobalt (Co), and molybdenum (Mo). The third protective layer 110 can be formed by physical vapor deposition such as ion beam deposition, sputtering, vacuum evaporation, molecular beam epitaxy, or an ion plating, etc.

The fourth protection layer 111 is disposed on the lower surface of the lower electrode 102. The lower electrode 102 is laminated on the substrate 101 via the fourth protective layer 111. The fourth protective layer 111 is formed using, for example, an alloy material which has iron (Fe) as main component. The fourth protective layer 111 is preferably formed using an alloy material containing Fe and at least any one selected from Co, Mo, Au, Pt, Al, Cu, Ag, Ta, Cr, Ti, Ni, Ir, Nb, Cs, Ba, V, W, and Ru. The fourth protective layer 111 is further preferably composed of an alloy material containing iron (Fe), cobalt (Co), and molybdenum (Mo). The fourth protective layer 111 can be formed by physical vapor deposition such as an ion beam deposition, sputtering, vacuum evaporation, molecular beam epitaxy, or ion plating, etc.

The thin-film piezoelectric actuator according to the present embodiment can achieve the same effects as the above-mentioned first embodiment. In addition, the first protective layer is provided on the upper surface of the upper electrode and the fourth protective layer is provided on the lower surface of the lower electrode to sandwich each thin-film piezoelectric film, so that compressive stress can be applied to each thin-film piezoelectric film. Therefore, the strength of the thin film piezoelectric actuator can be further improved. Furthermore, it is possible to prevent the peeling of the electrode by providing the third protective layer on the upper surface of the lower electrode.

### Fifth Embodiment

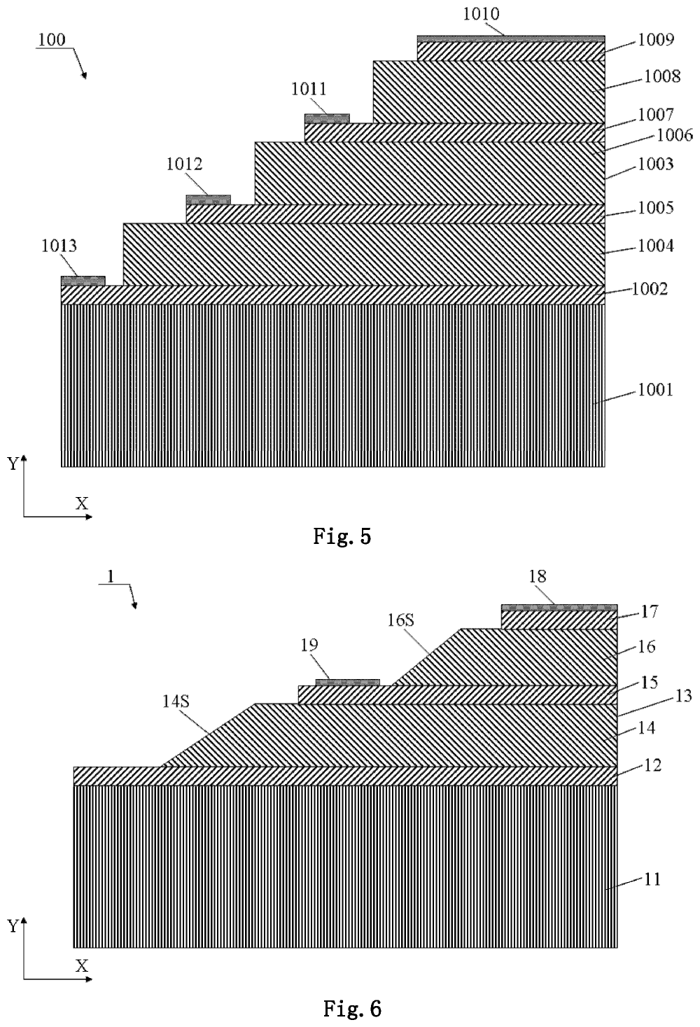

FIG. 5 is a schematic cross-sectional view showing the general structure of a thin film piezoelectric actuator according to a fifth embodiment. As shown in FIG. 5, the thin-film piezoelectric actuator 100 according to the present embodiment includes a substrate 1001, a lower electrode 1002, a laminated structure 1003, an upper electrode 1009, a first protective layer 1010, second protective layers 1011, 1012, and a third protective layer 1013.

The substrate 1001 is, for example, a silicon substrate, a silicon-on-insulator (SOI) substrate, a quartz glass substrate, a compound semiconductor substrate made of GaAs or the like, a sapphire substrate, a metal substrate made of stainless steel or the like, a MgO substrate, a SrTiO₃ substrate, or the like.

The lower electrode 1002 is laminated on the substrate 1001. The lower electrode 1002 is a thin-film made of metal element which has Pt (it may include Au, Ag, Pd, Ir, Ru, Cu, in addition to Pt) as main component, and is formed on the substrate 1001. A crystal structure of the lower electrode 1002 is a face-centered cubic structure.

The laminated structure 1003 is laminated on the lower electrode 1002, and includes three thin-film piezoelectric films 1004, 1006, and 1008 alternately laminated along the laminating direction Y with an intermediate electrode 1005 or an intermediate electrode 1007 sandwiched in between. That is, the laminated structure 1003 has a structure in which the thin-film piezoelectric film 1004, the intermediate electrode 1005, the thin-film piezoelectric film 1006, the intermediate electrode 1007, and the thin-film piezoelectric film 1008 are alternately laminated along the laminating direction Y in this order. Any two adjacent thin-film piezoelectric films share the intermediate electrode between them, that is, two adjacent thin-film piezoelectric films 1004 and 1006 share the intermediate electrode 1005 between them, and two adjacent thin-film piezoelectric films 1006 and 1008 share the intermediate electrode 1007 between them.

The thin-film piezoelectric films 1004, 1006, and 1008 are formed to be thin-film shape using piezoelectric materials such as lead zirconate titanate described by Pb (Zr,Ti) O₃ (which will also be referred to as “PZT” in the following) or the like. The thin-film piezoelectric films 1004, 1006, and 1008 are epitaxial films formed by epitaxial growth, and have a thickness of, for example, about 2 μm to 5 μm. In addition, a piezoelectric ceramics (much of them are ferroelectric substance) such as barium titanate, lead titanate or the like, or non-lead system piezoelectric ceramics not including lead are able to be used for the thin-film piezoelectric films 1004, 1006, and 1008 instead of using PZT. The thin-film piezoelectric films 1004, 1006, and 1008 are sputtered films formed by sputtering.

The upper electrode 1009 is laminated on the laminated structure 1003. The upper electrode 1009 is a thin-film made of metal material which has Pt (it may include Au, Ag, Pd, Ir, Ru, Cu, in addition to Pt) as main component, and is formed on the laminated structure 1003. A crystal structure of the lower electrode 1009 is a face-centered cubic structure.

The first protective layer 1010 is provided on the upper surface of the upper electrode 1009. The first protective layer 1010 is formed using, for example, an alloy material which has iron (Fe) as main component. The first protective layer 1010 is preferably formed using an alloy material containing Fe and at least any one selected from Co, Mo, Au, Pt, Al, Cu, Ag, Ta, Cr, Ti, Ni, Ir, Nb, Cs, Ba, V, W, and Ru. The first protective layer 1010 is further preferably composed of an alloy material containing iron (Fe), cobalt (Co), and molybdenum (Mo). The first protective layer 1010 can be formed by physical vapor deposition such as ion beam deposition, sputtering, vacuum evaporation, molecular beam epitaxy, or an ion plating, etc.

The second protective layer 1011 is provided on the upper surface of the end portion of the intermediate electrode 1007 that is not sandwiched between the thin-film piezoelectric films 1006 and 1008. The second protective layer 1012 is provided on the upper surface of the end portion of the intermediate electrode 1005 that is not sandwiched between the thin-film piezoelectric films 1004 and 1006. The second protective layers 1011 and 1012 are formed using, for example, an alloy material which has iron (Fe) as main component. The second protective layer 1011 and 1012 is preferably formed using an alloy material containing Fe and at least any one selected from Co, Mo, Au, Pt, Al, Cu, Ag, Ta, Cr, Ti, Ni, Ir, Nb, Cs, Ba, V, W, and Ru. The second protective layer 1011 and 1012 is further preferably composed of an alloy material containing iron (Fe), cobalt (Co), and molybdenum (Mo). The second protective layers 1011 and 1012 can be formed by physical vapor deposition such as ion beam deposition, sputtering, vacuum evaporation, molecular beam epitaxy, or ion plating, etc.

The third protective layer 1013 is provided on the upper surface of the end portion of the lower electrode 1002 that is not sandwiched between the substrate 1001 and the laminated body 1003. The third protective layer 1013 is formed using, for example, an alloy material which has iron (Fe) as main component. The third protective layer 1013 is preferably formed using an alloy material containing Fe and at least any one selected from Co, Mo, Au, Pt, Al, Cu, Ag, Ta, Cr, Ti, Ni, Ir, Nb, Cs, Ba, V, W, and Ru. The third protective layer 1013 is further preferably composed of an alloy material containing iron (Fe), cobalt (Co), and molybdenum (Mo). The third protective layer 1013 can be formed by physical vapor deposition such as ion beam deposition, sputtering, vacuum evaporation, molecular beam epitaxy, or ion plating, etc.

The thin-film piezoelectric actuator according to the present embodiment can achieve the same effects as the above-mentioned first embodiment. In addition, it is possible to prevent peeling of the electrode by providing the third protective layer on the upper surface of the lower electrode.

As mentioned above, the preferred embodiments of the present invention have been described. However, the present invention is not limited to the above-mentioned embodiments, and various changes can be made without departing from the gist of the present invention, and it goes without saying that these are also included in the scope of the present invention.

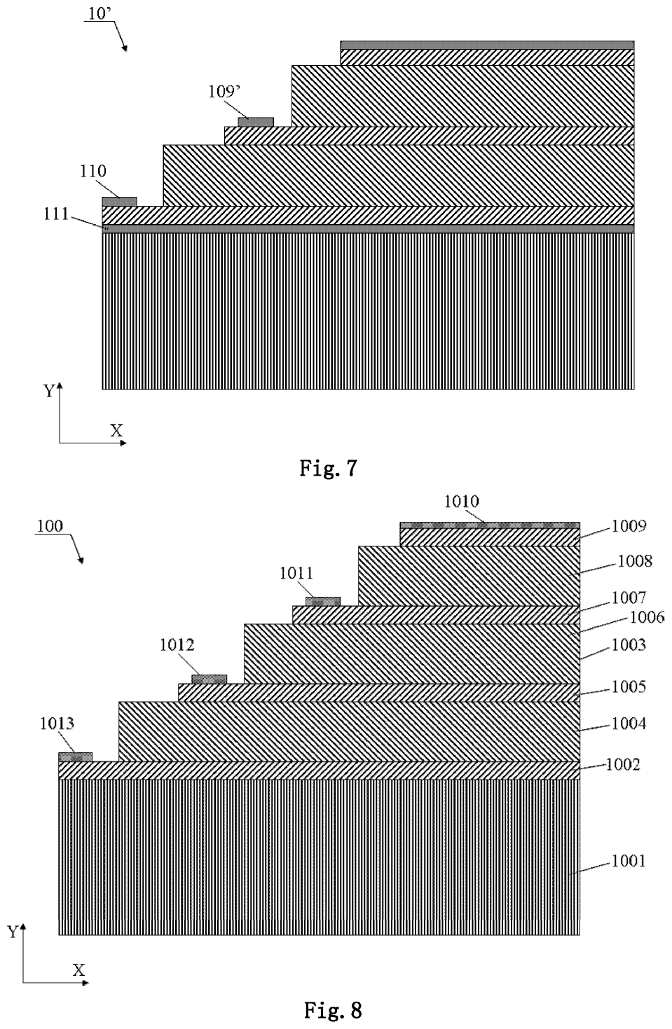

For example, in the first, fourth, and fifth embodiments described above, the second protective layer 19 covers up to the edge of the end portion of the intermediate electrode 15 that is not sandwiched between the thin-film piezoelectric films 14 and 16, the second protective layer 109′ covers up to the edge of the end portion of the intermediate electrode 105 that is not sandwiched between the thin-film piezoelectric films 104 and 106, the second protective layer 1011 covers up to the edge of the end portion of the intermediate electrode 1007 that is not sandwiched between the thin-film piezoelectric films 1006 and 1008, the second protective layer 1012 covers up to the edge of the end portion of the intermediate electrode 1007 that is not sandwiched between the thin-film piezoelectric films 1004 and 1006. However, it may be the same as the modification of the first embodiment shown in FIG. 6, the modification of the fourth embodiment shown in FIG. 7, and the modification of the fifth embodiment shown in FIG. 8, the second protective layer 19 does not cover up to the edge of the end portion of the intermediate electrode 15 that is not sandwiched between the thin-film piezoelectric films 14 and 16, but only covers the middle part of the upper surface of the end portion of the intermediate electrode 15 that is not sandwiched between the thin-film piezoelectric films 14, 16, the second protective layer 109′ does not cover up to the edge of the end portion of the intermediate electrode 105 that is not sandwiched between the thin-film piezoelectric films 104 and 106, but only covers the middle part of the upper surface of the end portion of the intermediate electrode 105 that is not sandwiched between the thin-film piezoelectric films 104 and 106, the second protective layer 1011 does not cover up to the edge of the end portion of the intermediate electrode 1007 that is not sandwiched between the thin-film piezoelectric films 1006 and 1008, but only covers the middle part of the upper surface of the end portion of the intermediate electrode 1007 that is not sandwiched between the thin-film piezoelectric films 1006 and 1008, the second protective layer 1012 does not cover up to the edge of the end portion of the intermediate electrode 1007 that is not sandwiched between the thin-film piezoelectric films 1004 and 1006, but only covers the middle part of the upper surface of the end portion of the intermediate electrode 1007 that is not sandwiched between the thin-film piezoelectric films 1004 and 1006.

1. A thin-film piezoelectric actuator comprising:
a substrate;
a lower electrode laminated on the substrate;
a laminated structure configured to be laminated on the lower electrode and including a plurality of thin-film piezoelectric films alternately laminated with an intermediate electrode sandwiched in between;
an upper electrode laminated on the laminated structure;
a first protective layer configured to be provided on an upper surface of the upper electrode and made of an alloy material containing iron, cobalt, and molybdenum; and
a second protective layer configured to be provided at least on an upper surface of an end portion of the intermediate electrode that is not sandwiched between the thin-film piezoelectric films, and made of an alloy material containing iron, cobalt, and molybdenum.

2. The thin-film piezoelectric actuator according to claim 1,
wherein the second protective layer is continuously provided on the entire surface of the upper surface of the end portion of the intermediate electrode that is not sandwiched between the thin-film piezoelectric films and a part of an end surface of the thin-film piezoelectric film.

3. The thin-film piezoelectric actuator according to claim 1,
wherein the second protective layer is continuously provided on the entire surface of the upper surface of the end portion of the intermediate electrode that is not sandwiched between the thin-film piezoelectric films, the entire surface of an end surface of the thin-film piezoelectric film, and a part of an upper surface of the thin-film piezoelectric film.

4. The thin-film piezoelectric actuator according to claim 1,
wherein an end surface of the thin-film piezoelectric film is an inclined surface that is inclined with respect to a direction in which the plurality of thin-film piezoelectric films are laminated.

5. The thin-film piezoelectric actuator according to claim 1,
wherein an end surface of the thin-film piezoelectric film is a vertical surface parallel to a direction in which the plurality of thin-film piezoelectric films are laminated.

6. The thin-film piezoelectric actuator according to claim 1, further comprising:
a third protective layer configured to be provided on an upper surface of an end portion of the lower electrode that is not sandwiched between the substrate and the laminated structure and made of an alloy material containing iron, cobalt, and molybdenum.

7. The thin-film piezoelectric actuator according to claim 1, further comprising:
a fourth protective layer configured to be provided on a lower surface of the lower electrode and made of an alloy material containing iron, cobalt, and molybdenum,
the lower electrode is laminated on the substrate via the fourth protective layer.
